(19) United States
(12) Patent Application Publication
(10) Pub. No.: US 2026/0190863 A1
(43) Pub. Date: Jul. 2, 2026

(54) PIEZOELECTRIC-ON-INSULATOR (POI) SUBSTRATE, AND PROCESS FOR MANUFACTURING A PIEZOELECTRIC-ON-INSULATOR (POI) SUBSTRATE

(71) Applicant: SOITEC, Bernin (FR)

(72) Inventors: Marcel Broekaart, BERNIN (FR); Alexis Drouin, BERNIN (FR); Oleg Kononchuk, BERNIN (FR); Luciana Capello, BERNIN (FR); Brice Tavel, BERNIN (FR); Isabelle Bertrand, BERNIN (FR); Morgane Logiou, BERNIN (FR)

(21) Appl. No.: 19/125,024

(22) PCT Filed: Oct. 26, 2023
(86) PCT No.: PCT/EP2023/079957

§ 371 Date: Apr. 28, 2025

(30) Foreign Application Priority Data
Oct. 26, 2022 (FR) 2211174

(51) Int. Cl. H10N 30/00; H10N 30/073; H10N 30/853

(52) U.S. Cl. CPC H10N 30/708; H10N 30/073; H10N 30/8542

(57) ABSTRACT

A piezoelectric-on-insulator (POI) substrate includes a carrier substrate comprising a trapping layer on a free surface of the carrier substrate, a piezoelectric layer, an intermediate structure sandwiched between the piezoelectric layer and the trapping layer of the carrier substrate, wherein the intermediate structure comprises at least one tantalum oxide (Ta₂O₅)-based diffusion barrier layer that prevents the diffusion of metal elements and has a thickness/_{EM} greater than a predetermined thickness, the predetermined thickness being determined according to the thickness of the trapping layer such that the metal element dose in the trapping layer is lower than a predetermined threshold dose. A method may be used to manufacture such a piezoelectric-on-insulator (POI) substrate.

### CROSS-REFERENCE TO RELATED APPLICATIONS

This application is a national phase entry under 35 U.S.C. § 371 of International Patent Application PCT/EP2023/079957, filed Oct. 26, 2023, designating the United States of America and published as International Patent Publication WO 2024/089187 A1 on May 2, 2024, which claims the benefit under Article 8 of the Patent Cooperation Treaty of French Patent Application Serial No. FR2211174, filed Oct. 26, 2022.

### TECHNICAL FIELD

The present disclosure relates to a piezoelectric-on-insulator (POI) substrate and a process for manufacturing such a piezoelectric-on-insulator (POI) substrate.

### BACKGROUND

A piezoelectric-on-insulator (POI) substrate is used for acoustic wave devices, such as sensors, filters and the like, because it achieves good performance thanks to better values of quality Q and electromechanical coefficients k compared with other substrates in the prior art.

Such a substrate comprises a thin layer of piezoelectric material on a dielectric layer, itself arranged on a carrier substrate. For certain applications, a trapping layer is placed between the carrier substrate and the dielectric layer. The trapping layer is typically a non-crystalline layer having structural defects such as dislocations, grain boundaries, amorphous regions, interstices, inclusions, and/or pores. These structural defects act as traps for charges that may circulate within the material. The trapping layer thus has a high resistivity, resulting in reduced charge conduction within the layer, and consequently reduced current within the trapping layer. The trapping layer reduces losses due to parasitic conduction effects at the interface between the carrier substrate and the dielectric layer. In fact, the trapping layer serves to reduce the lifetime of the charges in this region.

When manufacturing such a piezoelectric-on-insulator (POI) substrate, a donor substrate is used wherein a substrate of piezoelectric material is joined to a handling substrate. Next, the donor substrate undergoes a thinning step of the piezoelectric substrate to form a thinner piezoelectric layer before being bonded to the carrier substrate. Finally, the transfer of a piezoelectric thin film onto the carrier substrate is mechanically or thermally transferred to the carrier substrate at a fracture zone previously created in the piezoelectric layer of the donor substrate. A final heat treatment of the resulting substrate (POI) is required to repair the damage caused to the piezoelectric layer transferred during the fracturing step.

However, this final annealing results in the diffusion of metal elements (Li, Fe, Cu, Ni) from the piezoelectric layer to the trapping layer. When metal elements diffuse into the trapping layer, they neutralize (occupy) electrical traps present in the trapping layer. This neutralization of the electrical traps in the trapping layer results in a degradation of the electrical performance of the trapping layer, in particular, a reduction in Q factor and radio frequency performance, and consequently also that of the POI substrate thus manufactured.

The present disclosure thus remedies the aforementioned drawbacks and, in particular, designs a piezoelectric-on-insulator (POI) substrate with improved characteristics for use in acoustic wave devices.

### BRIEF SUMMARY

One embodiment of the disclosure is realized by a piezoelectric-on-insulator (POI) substrate comprising a carrier substrate, in particular, a silicon-based substrate, comprising a trapping layer on a free surface of the carrier substrate, in particular, a polycrystalline or amorphous or porous silicon-based layer, a piezoelectric layer, in particular, a layer of lithium tantalate (LiTaO₃) or lithium niobate (LiNbO₃), and an intermediate structure sandwiched between the piezoelectric layer and the trapping layer of the carrier substrate, wherein the intermediate structure comprises at least one Tantalum Oxide (Ta₂O₅)-based diffusion barrier layer for metal elements, in particular, lithium, having a thickness t_{EM} greater than a predetermined thickness, the predetermined thickness being determined as a function of the thickness of the trapping layer in such a way that the metal element dose in the trapping layer is less than a predetermined threshold dose, in particular, a threshold metal element dose of less than 10¹² at/cm², in particular, less than 5×10¹¹ at/cm².

The presence of the metal element diffusion barrier structure between the piezoelectric layer and the trapping layer reduces metal element diffusion from the piezoelectric layer to the trapping layer during the manufacturing process. In this way, the neutralization of charge traps present in the trapping layer by metal elements is reduced. The trapping layer in the final substrate (POI) therefore has a high resistivity, resulting in a substrate (POI) with improved performance.

The threshold thickness of the barrier layer is determined as a function of the thickness of the trapping layer and the threshold dose of metal elements present in the trapping layer, for which the trapping layer still has electrical characteristics that enable a POI substrate with improved performance to be obtained.

According to a variant of the disclosure, the barrier layer can have a thickness of between 5 nm and 150 nm, and the thickness of the trapping layer is between 50 nm and 5 μm. The barrier layer is much thinner than the trapping layer.

According to one variant of the disclosure, the intermediate structure can comprise at least one dielectric layer, in particular, based on silicon dioxide or silicon nitride (SiN) or silicon oxynitride (SiOₓN_{y}), in contact with the at least one barrier layer. The dielectric layer ensures good adhesion in the POI substrate between the piezoelectric material and the carrier substrate.

In one embodiment, the barrier layer that prevents the diffusion of metal elements can be sandwiched between two dielectric layers.

According to one variant of the disclosure, the intermediate structure can additionally comprise a second barrier layer. A second barrier layer provides a substrate (POI) with improved electrical characteristics and therefore better performance for SAW applications. Indeed, the second barrier layer can be a second diffusion barrier layer for blocking the same metal element as the first diffusion barrier layer from the piezoelectric layer to the trapping layer, or the second barrier layer can be a diffusion barrier layer for blocking another metal element as the first barrier layer in the composite substrate.

According to a variant of the disclosure, the second barrier layer can be a hydrogen diffusion barrier layer, in particular, based on silicon oxynitride (SiOₓN_{y}), silicon nitride (SiN) or aluminum nitride (AlN). In a piezoelectric-on-insulator (POI) substrate, hydrogen diffusion to the piezoelectric layer and/or the trapping layer occurring during heat treatment steps in the process for manufacturing such a substrate also reduces the performance of the piezoelectric-on-insulator (POI) substrate. In this way, the presence of a hydrogen barrier layer reduces hydrogen diffusion inside the piezoelectric-on-insulator (POI) substrate during the manufacture of the substrate (POI), resulting in a POI substrate with improved performance.

According to a variant of the disclosure, the intermediate layer can comprise at least one layer with a hydrogen concentration of less than 10²⁰ at/cm³, in particular, less than 10¹⁸ at/cm³. A layer with a hydrogen concentration of less than 10²⁰ at/cm³ corresponds to a hydrogen diffusion barrier layer. As a result, the POI substrate has improved performance thanks to the presence of such a layer in its structure.

The object of the disclosure is also realized by a previously described process for manufacturing a piezoelectric-on-insulator (POI) substrate comprising the steps of providing a carrier substrate, in particular, a silicon-based substrate, comprising a trapping layer, in particular, a polycrystalline or amorphous or porous silicon-based layer, providing a substrate comprising a piezoelectric layer, in particular, a piezoelectric layer based on lithium tantalate (LiTaO₃) or lithium niobate (LiNbO₃), forming an intermediate structure on the substrate comprising a piezoelectric layer and/or on the carrier substrate, the formation of the intermediate structure comprising the formation of at least one barrier layer that prevents the diffusion of metal elements, in particular, lithium, based on tantalum oxide (Ta₂O₅), the barrier layer having a thickness t_{EM} greater than a predetermined thickness, the predetermined thickness being determined according to the thickness of the trapping layer in such a way that the metal element dose in the trapping layer is less than a predetermined threshold dose, in particular, a metal element threshold dose, even more in particular, a lithium dose, in particular, a threshold dose of less than 1.2×10¹² at/cm², in particular, less than 5×10¹¹ at/cm², and join the substrate comprising a piezoelectric layer with the carrier substrate.

Thus, the step of forming an intermediate structure on the substrate comprising a piezoelectric layer and/or the carrier substrate in the process according to the disclosure makes it possible to form a metal element diffusion barrier layer to reduce metal element diffusion from the piezoelectric layer to the trapping layer during heat treatment steps of the process. With this process, a substrate can be obtained that effectively reduces the negative effect of metal elements diffusing into the carrier substrate and, in particular, into the carrier substrate's trapping layer.

According to one variant of the disclosure, the step of forming the intermediate structure may additionally comprise the formation of a second barrier layer. The second barrier layer can be a barrier layer of metal elements or a barrier layer of another element in the structure, in particular, a non-metal element. With this process, a substrate can be obtained that even more effectively reduces the negative effect of element diffusion to the carrier substrate by reducing both metal element diffusion from the piezoelectric layer and diffusion of other elements into the structure of the POI substrate.

According to one variant of the disclosure, the step of forming the intermediate structure can further comprise a step of forming a layer with a hydrogen concentration of less than 10²⁰ at/cm³, in particular, less than 10¹⁸ at/cm³. The formation of a layer with a reduced hydrogen concentration limits hydrogen diffusion into the structure during subsequent heat treatment, which is known to facilitate hydrogen diffusion to the piezoelectric and/or trapping layer.

According to one variant of the disclosure, the step of forming the second barrier layer may comprise the formation of a layer based on silicon nitride (SiN), silicon oxynitride (SiOₓN_{y}) or aluminum nitride (AlN). A layer based on such a material provides a barrier blocking hydrogen diffusion towards the piezoelectric layer and/or the trapping layer.

According to a variant of the disclosure, the process may further comprise a step of forming a dielectric layer on the carrier substrate and/or on the substrate comprising a piezoelectric layer prior to the bonding step, such that the bonding interface is an oxide-oxide bonding interface. The assembly interface between the carrier substrate and the substrate comprising a layer is made at the interface between two dielectric layers, with oxide-oxide type bonds, in particular, a Si—O—Si type bond, which is a type of bond known to be stable. In this way, the piezoelectric-on-insulator substrate obtained by the process according to the disclosure has a stable bond between the piezoelectric layer and the carrier substrate.

According to one variant of the disclosure, the manufacturing process may further comprise a step of forming a dielectric layer of a first material on the carrier substrate and/or of a second material different from the first material on the substrate comprising a piezoelectric layer prior to the assembly step. For example, the first material is based on silicon nitride, in particular, Si₃N₄, and the second material is based on silicon oxynitride (SiOₓN_{y}), in particular, SiON. Thus, the bonding interface is a Si₃N₄—SiOₓN_{y} bonding interface. Such an interface offers advantages in terms of the acoustic impedance of the manufactured structure, as well as being a stable assembly interface.

### BRIEF DESCRIPTION OF THE DRAWINGS

The disclosure and its advantages will be explained in greater detail below by means of preferred embodiments and with particular reference to the following accompanying figures, wherein the reference numbers identify features of the disclosure.

FIG. 1 schematically shows a process for manufacturing a piezoelectric-on-insulator (POI) substrate according to a first embodiment of the disclosure.

FIG. 2A schematically shows a process for manufacturing a piezoelectric-on-insulator (POI) substrate according to a second embodiment of the disclosure.

FIG. 2B schematically shows a process for manufacturing a donor substrate and a donor substrate according to a first variant of the second embodiment of the disclosure.

FIG. 2C schematically shows a process for manufacturing a piezoelectric-on-insulator (POI) substrate according to a second variant of the second embodiment of the disclosure.

FIG. 3 schematically shows a process for manufacturing a piezoelectric-on-insulator (POI) substrate according to a third embodiment of the disclosure.

### DETAILED DESCRIPTION

The disclosure will be described in more detail using advantageous embodiments in an exemplary manner and with reference to the drawings. The embodiments described are merely possible configurations and it should be borne in mind that individual features as described above may be provided independently of each other or may be omitted altogether when implementing the present disclosure.

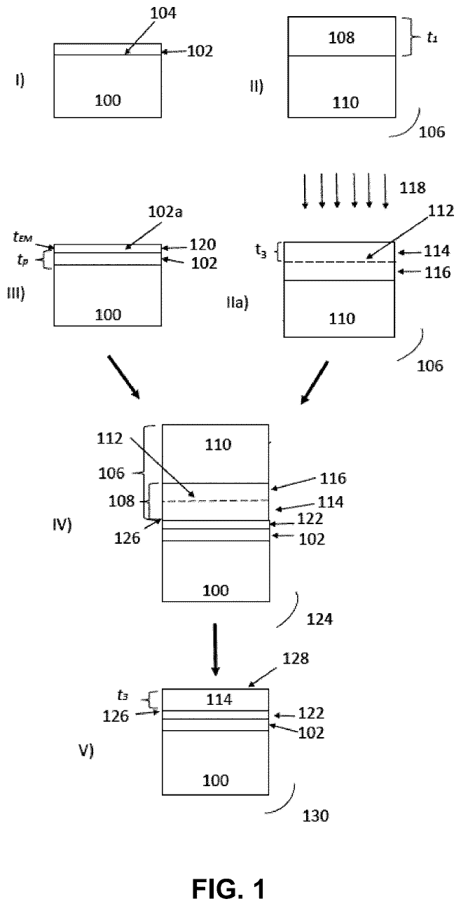

FIG. 1 schematically shows a process for manufacturing a piezoelectric-on-insulator (POI) substrate according to the first embodiment of the disclosure.

The process for manufacturing a piezoelectric-on-insulator (POI) substrate begins with step I) of providing a carrier substrate 100, in particular, a bulk substrate. A bulk substrate is a substrate based on a single material, typically between 200 μm and 1 mm thick.

The carrier substrate 100 can be based on silicon, sapphire, aluminum nitride (AlN), silicon carbide (SiC) or gallium arsenide (GaAs). The carrier substrate 100 can be a crystalline or polycrystalline substrate.

The carrier substrate 100 comprises a trapping layer 102 deposited on a free surface 104 of the carrier substrate by a deposition technique, such as sub-atmospheric pressure chemical vapor deposition (LPCVD) or plasma-enhanced (PECVD) or non-plasma-enhanced chemical vapor deposition (CVD). The deposition temperature is between 200° C. and 1100° C. The trapping layer 102 is a silicon-based layer, for example, based on polycrystalline silicon or amorphous silicon or porous silicon, polished or not polished. The thickness tₚ of the trapping layer 102 is between 5 nm and 5 μm.

The trapping layer 102 is thus a non-crystalline layer having structural defects such as dislocations, grain boundaries, amorphous regions, interstices, inclusions, and/or pores. These structural defects form traps for charges likely to circulate in the material, for example, at incomplete or pendant chemical bonds. The trapping layer 102 thus has a high resistivity, resulting in reduced charge conduction within the layer, and consequently reduced current within the trapping layer.

In step II) of the process according to the first embodiment, a substrate comprising a piezoelectric layer 106 is provided. This is preferably a thick layer of piezoelectric material 108 of thickness ti, provided on a base substrate 110.

The piezoelectric material of piezoelectric layer 106 can be a lithium-rich piezoelectric material, for example, lithium tantalate (LiTaO₃) or lithium niobate (LiNbO₃).

The substrate comprising a piezoelectric layer 106 may first have undergone one or more steps of cleaning, brushing, or polishing its free surface to remove particles or dust and thus obtain a cleaner, higher-quality free surface for subsequent deposition of successive layers.

According to the disclosure, a step III) of depositing an intermediate structure 120 on the free surface 102a, preferably directly on the free surface 102a, of the trapping layer 102 of the carrier substrate 100 is carried out.

Step III) of depositing the intermediate structure 120 comprises the formation of at least one metal element diffusion barrier layer 122. The barrier layer 122 can be a lithium diffusion barrier layer 122.

The barrier layer 122 can, according to the disclosure, be an amorphous layer based on tantalum oxide (Ta₂O₅) deposited by an atomic layer deposition (ALD) technique, or by plasma enhanced atomic layer deposition (PE-ALD), or by low pressure chemical vapor deposition (LPCVD), by metal-organic chemical vapor deposition (MOCVD) or by plasma-enhanced atomic layer deposition (PE-ALD): low-pressure chemical vapor deposition (LPCVD), metal-organic chemical vapor deposition (MOCVD) or plasma-enhanced chemical vapor deposition (PECVD).

In this case, the deposition temperature for ALD is between 25° C. and 350° C. or for LPCVD between 500 and 800° C., for MOCVD between 50° and 800° C. or for PECVD between 250 and 400° C. followed by heat treatment at 700° C.

The barrier layer 122 has a thickness t_{EM} greater than a predetermined thickness, the predetermined thickness being defined as a function of the thickness tₚ of the trapping layer 102 in such a way that the dose of metal element in the trapping layer 102 is less than a threshold dose of metal element causing degradation of the trapping layer 102.

To calculate the threshold dose of metal element, the skilled person will know how to calculate the diffusion slope of the metal element from its diffusion coefficient and thus adjust the thickness t_{EM} of the barrier layer 122 to ensure that a predetermined threshold dose of metal element is not exceeded in the trapping layer 102. This calculation also depends on the heat treatments applied to the structure during the manufacturing process and also on the thickness of the trapping layer 102.

For example, for a layer of lithium tantalate (LiTaO₃) or lithium niobate (LiNbO₃) and for a trapping layer 102 with a thickness tₚ of 1 μm, the threshold dose of lithium in the trapping layer 102 must be less than 10¹² at/cm². For a trapping layer 102 with a thickness tₚ of the order of 0.5 μm, the threshold dose of lithium will be of the order of 5×10¹¹ at/cm².

To obtain these values, the thickness t_{EM} of the barrier layer 122 must be between 5 nm and 150 nm, in particular, between 10 nm and 100 nm.

In step IIa), an embrittlement zone 112 is formed in the piezoelectric layer 108 of the substrate comprising a piezoelectric layer 106, so as to delimit the piezoelectric layer 114 to be transferred from the remainder 116 of the piezoelectric layer 108 of the substrate comprising a piezoelectric layer 106.

This step IIa) of forming an embrittlement zone 112 is carried out by implanting 118 atomic or ionic species into the piezoelectric layer 108 of the substrate comprising a piezoelectric layer 106. The atomic or ionic implantation is carried out in such a way that the embrittlement zone 112 is located inside the film of piezoelectric material 108 and separates a piezoelectric layer 116 from the rest 114 of the film of piezoelectric material 108. The atomic or ionic species are implanted at a specific depth t₃ of the piezoelectric layer 108, which determines the thickness t₃ of the piezoelectric layer 114 to be transferred. The thickness t₃ is typically between 50 nm and 1.2 μm, in particular, of the order of 800 nm. The implantation dose of atomic or ionic species is between 10¹⁶ at/cm² and 10¹⁷ at/cm². The carrier substrate 100 obtained after step III) is then assembled with the donor substrate 110 obtained after step IIa) during assembly step IV) to obtain a heterostructure 124 corresponding to the carrier substrate-donor substrate assembly. Here, the assembly is bonded by molecular adhesion.

The substrate comprising a piezoelectric layer 106 is assembled on the carrier substrate 100 in such a way that the barrier layer 122 of the intermediate structure 120 is sandwiched between the piezoelectric layer 114 of the substrate comprising a piezoelectric layer 106 and the trapping layer 102 of the carrier substrate 100. The contact interface 126 is located between the piezoelectric layer 114 and the intermediate structure 120 of the carrier substrate 100.

Next, step V) of transferring the piezoelectric thin film 114 is carried out. To do so, a step of fracturing the donor substrate 124 by supplying thermal energy with a heat treatment between 100° C. and 300° C. in an Ar or N₂ atmosphere, and/or mechanically at the embrittlement zone 112 to obtain a POI substrate comprising a piezoelectric layer 114 with a thickness t₃ typically between 50 nm and 1 μm, in particular, of the order of 600 nm.

The piezoelectric-on-insulator (POI) substrate 130 obtained after step V) is heat-treated to repair the damage caused to the piezoelectric layer 114 transferred during the fracturing step. This heat treatment is carried out at a temperature of between 40° and 600° C., in particular, around 500° C., in an atmosphere of Ar, O₂ or N₂.

During heat treatment of the POI substrate, metal elements may diffuse from the piezoelectric layer 114 towards the trapping layer 102.

Thanks to the presence of the barrier layer 122, metal element diffusion from the piezoelectric layer 114 to the trapping layer 102 is reduced, as the barrier layer 122 acts as a metal element diffusion barrier layer. In this way, the passivation of the charge traps in the trapping layer 102 by metal elements from the piezoelectric layer 114 is reduced, and the trapping layer 102 retains its power to reduce parasitic currents.

In a variant of the process according to the first embodiment, the intermediate structure 120 is formed by a plurality of layers of tantalum oxide (Ta₂O₅) and layers based on another oxide, for example, silicon oxide or silicon nitride (SiN) or silicon oxynitride (SiOₓN_{y}), interposed between them. The thickness of each oxide layer is between 5 nm and 100 nm.

In a variant of the process according to the first embodiment, the intermediate structure 120, here the metal element diffusion barrier layer 122, is produced on the piezoelectric layer 108 of the substrate comprising a piezoelectric layer 106, instead of on the carrier substrate 100. In this case, the step of forming the barrier layer 122 is carried out before or after the step of forming the embrittlement zone 112 in the piezoelectric layer 108. The assembly interface of the carrier substrate 100 with the substrate comprising a piezoelectric layer 106 is then made at the interface located between the barrier layer 122 of the substrate comprising a piezoelectric layer 106 and the trapping layer 102 of the carrier substrate 100.

In another variant of the process according to the first embodiment, the intermediate structure 120, here the barrier layer 122, can be provided on the substrate comprising a piezoelectric layer 106 and on the carrier substrate 100. In this case, the step of forming the barrier layer 122 is carried out before or after the step of forming the embrittlement zone 112 in the piezoelectric layer 108. The assembly interface of the carrier substrate 100 with the substrate comprising a piezoelectric layer 106 is then made at the interface between two barrier layers. Assembling the substrate comprising a piezoelectric layer onto the carrier substrate by assembling two barrier layers is advantageous for assembly, as it takes place between two layers of the same material.

In a variant of the process, instead of carrying out step IIa) of forming the embrittlement zone in the piezoelectric layer 108 of the substrate comprising a piezoelectric layer 106, after step III), assembly step IV) is carried out directly between the substrate comprising a piezoelectric layer 106 and the carrier substrate 100. A thinning step IVa) (not shown) is then carried out to reduce the thickness of the substrate comprising a piezoelectric layer 106. This thinning step can be a step of grinding the substrate comprising a piezoelectric layer 106 to obtain a piezoelectric layer 114 with a thinner thickness than the piezoelectric layer 108.

In addition, further treatments of the free surface 128 of the piezoelectric layer 114 can be carried out to improve the quality of the free surface 128 of the piezoelectric layer 114.

The piezoelectric-on-insulator (POI) substrate 130 shown in step V) of FIG. 1 obtained with the carrier substrate 100, the trapping layer 102, the metal element diffusion barrier layer 122, and the piezoelectric layer 114 corresponds to the substrate according to the disclosure according to the first embodiment as well.

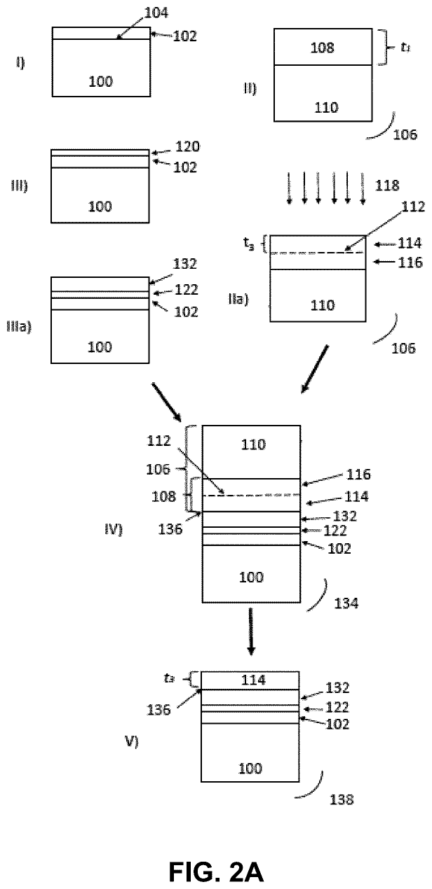

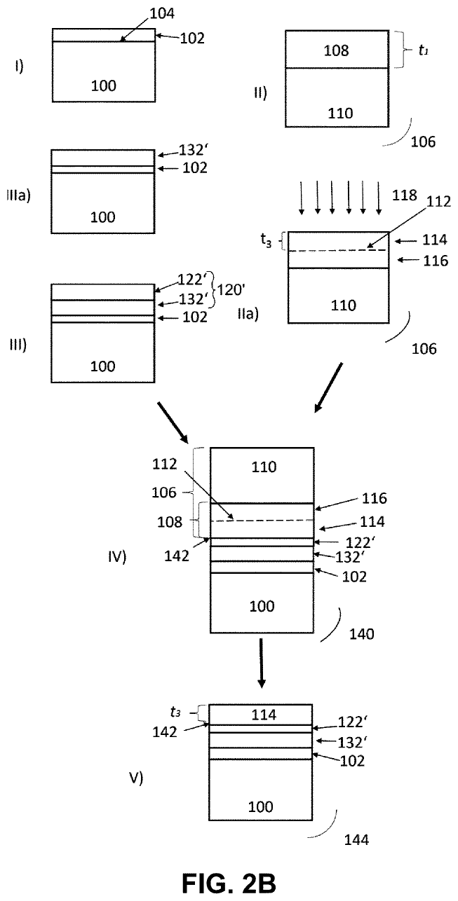

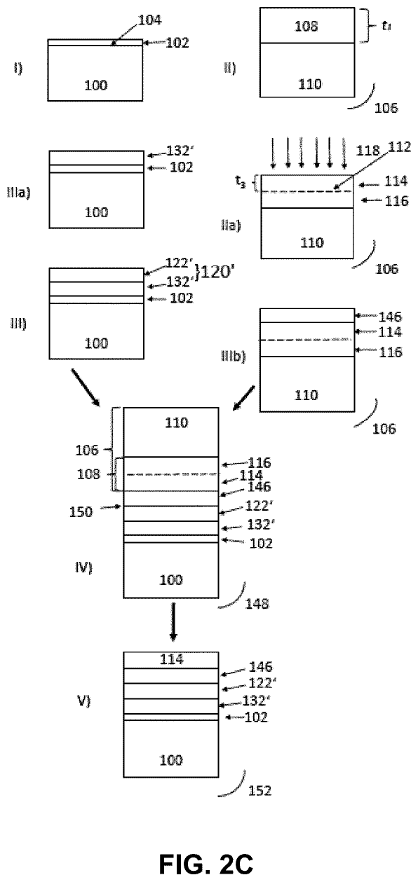

FIG. 2A schematically shows a process for manufacturing a piezoelectric-on-insulator (POI) substrate according to a second embodiment of the disclosure.

In this second embodiment, the only difference with the process according to the first embodiment is that the deposition step III) of the intermediate structure 120 additionally comprises a step IIIa) of forming a dielectric layer 132 on, in particular, in direct contact with, the at least one barrier layer 122. Thus, the intermediate structure 120 comprises a metal element diffusion barrier layer 122 and a dielectric layer 132.

The other steps I) to V) are the same as in the first embodiment, except that in step IV) the dielectric layer 132 is joined to the substrate comprising a piezoelectric layer 106. All features in common with the first embodiment and its variant and using the same reference numbers as above will not be described again, but reference is made to their detailed description above.

The dielectric layer 132 is, for example, a silicon oxide-based layer. But the dielectric layer 132 can also be a layer of silicon nitride (Si₃N₄), or a layer comprising a combination of silicon nitride and oxide (SiOₓN_{y}), or a superposition of a layer of silicon oxide and a combination of silicon nitride and oxide (SiOₓN_{y}) or a superposition of a layer of silicon oxide and a layer of silicon nitride.

The dielectric layer 132 is produced by a deposition technique such as CVD or LPCVD (chemical vapor deposition), PECVD (plasma-enhanced chemical vapor deposition) or PVD (physical vapor deposition), or by oxidation heat treatments. PVD deposition involves deposition temperatures between room temperature and 400° C., while PECVD technique involves deposition temperatures between 150° C. and 400° C. LPCVD deposition involves deposition temperatures between 60° and 700° C. The dielectric layer 132 is deposited on and, in particular, directly in contact with, the barrier layer 122.

Heat treatment, also known as densification treatment, can be carried out after deposition of the dielectric layer 132 to degas the excess hydrogen formed during deposition, which occupies the traps in the trapping layer 102. In addition, or alternatively, a surface treatment can be carried out to improve the surface quality of the deposited dielectric layer 132.

The dielectric layer 132 is, for example, a silicon dioxide-based layer. But the dielectric layer 132 can also be a layer comprising a combination of silicon nitride and oxide (SiOₓN_{y}), or a superposition of a silicon oxide layer and a combination of silicon nitride and oxide (SiOₓN_{y}), or a layer of silicon nitride (Si₃N₄), or a layer comprising a combination of silicon nitride and oxide (SiOₓN_{y}), or a superposition of a layer of silicon oxide and a layer of silicon nitride.

Thus, in assembly step V), the substrate comprising a piezoelectric layer 106 is assembled with the carrier substrate 100 to form the heterostructure 134, by bringing the dielectric layer 132 into contact with the piezoelectric layer 108 of the substrate comprising a piezoelectric layer 106. Thus, in this second embodiment, the assembly interface 136 is located between the piezoelectric layer 108 and the dielectric layer 132 of the carrier substrate 100.

In one embodiment, the dielectric layer 132 can be a layer with a hydrogen concentration of less than 10²⁰ at/cm³, in particular, less than 10¹⁸ at/cm³. After deposition of the dielectric layer 132 at a temperature typically between a room temperature and 7000° C., depending on the deposition technique used, densification annealing can be carried out to reduce the concentration of hydrogen in the dielectric layer 132. For example, if the dielectric layer is produced by PVD deposition, the temperature is between room temperature and 400° C., for PECVD deposition, between 150° C. and 400° C., for LPCVD deposition between 600° C. and 7000° C., and for thermal oxidation, the temperature is between 800° C. and 1000° C.

This annealing is annealing in a hydrogen-depleted atmosphere (i.e., less than 5 ppm), and exposes the silicon oxide-based dielectric layer 132 to a temperature that is much greater than its deposition temperature. This can be a neutral or oxidizing atmosphere. Preferentially, this temperature is greater than 800° C., typically between 800° C. and 100° C. The annealing stage is continued for at least one hour, and preferentially for several hours, so as to finally exodiffuse the hydrogen from the dielectric layer 132, and optionally from the trapping layer 102. After this densification annealing, the dielectric layer 132 has a hydrogen concentration of less than 10²⁰ at/cm³.

In one embodiment, the dielectric layer 132 can be provided on the piezoelectric layer 108 of the substrate comprising a piezoelectric layer 106 instead of on the carrier substrate 100. In this case, the step of forming the dielectric layer 132 is carried out after or before the step of forming the embrittlement zone 112 in the piezoelectric layer 108. In this case, the assembling of the carrier substrate 100 with the substrate comprising a piezoelectric layer 106 takes place at the interface between the dielectric layer 132 of the piezoelectric substrate 106 and the intermediate structure 120 of the carrier substrate 100.

In another variant, a dielectric layer can be provided on both substrates, the substrate comprising a piezoelectric layer 106 and on the carrier substrate 100. In this case, the step of forming the dielectric layer is carried out before or after the step of forming the embrittlement zone 112 in the piezoelectric layer 108. The assembling of the carrier substrate 100 with the substrate comprising a piezoelectric layer 106 then takes place at the interface between two dielectric layers.

For example, it is done with oxide-oxide bonds, in particular, a Si—O—Si bond, which enables stable molecular force bonding.

In another embodiment, a dielectric layer of a first material can be provided on the substrate comprising a piezoelectric layer 106 and a dielectric layer of a second material can be provided on the carrier substrate 100, the first material being different from the second material. For example, the dielectric layer provided on the substrate comprising a piezoelectric layer 106 is a layer of Si₃N₄, while the dielectric layer provided on the carrier substrate 100 is a layer of SiOₓN_{y}, in particular, SiON. Thus, the assembly of the carrier substrate 100 with the substrate comprising a piezoelectric layer 106 is then carried out at the interface between two dielectric layers Si₃N₄—SiOₓN_{y}, which allows a stable bond.

In one embodiment, the dielectric layer 132 and barrier layer 122 of the intermediate structure 120 can be provided on the piezoelectric layer 108 of the substrate comprising a layer 106 instead of on the carrier substrate 100. In this case, the step of forming the intermediate structure 120 is carried out before or after the step of forming the embrittlement zone 112 in the piezoelectric layer 108. In this case, assembly of the carrier substrate 100 with the substrate comprising a piezoelectric layer 106 takes place at the interface between the dielectric layer 132 of the intermediate structure 120 on the substrate comprising a piezoelectric layer 106 and the trapping layer 102 of the carrier substrate 100.

The piezoelectric-on-insulator (POI) substrate 138 shown in step V) of FIG. 2A obtained with the carrier substrate 100, the trapping layer 102, the metal element diffusion barrier layer 122, the dielectric layer 132, and the piezoelectric layer 114 corresponds to the substrate according to the disclosure according to the second embodiment as well.

In one variant, shown in FIG. 2B, step IIIa) of forming a dielectric layer 132′ is carried out before step III) of forming the at least one barrier layer 122′. The dielectric layer 132′ and barrier layer 122′ are made in the same way as the dielectric layer 132 and barrier layer 122 previously described in FIG. 2A. Thus, the intermediate structure 120′ comprises the dielectric layer 132′ and the metal element diffusion barrier layer 122′.

Thus, in assembly step IV), the substrate comprising a piezoelectric layer 106 is assembled with the carrier substrate 100 to form the heterostructure 140 by bringing the barrier layer 122′ into contact with the piezoelectric substrate 106. Thus, in this variant, assembly takes place at the interface 142 between the substrate comprising a piezoelectric layer 106 and the barrier layer 122′ of the carrier substrate 100.

In one embodiment, the barrier layer 122′ can be provided on the piezoelectric layer 108 of the substrate comprising a layer 106 instead of on the carrier substrate 100. In this case, the step of forming the barrier layer 122′ is carried out before or after the step of forming the embrittlement zone 112 in the piezoelectric layer 108. In this case, assembly of the carrier substrate 100 with the substrate comprising a piezoelectric layer 106 takes place at the interface between the barrier layer 122′ on the substrate comprising a piezoelectric layer 106 and the trapping layer 132′ of the carrier substrate 100.

In another variant, the barrier layer 122′ can be provided on the substrate comprising a piezoelectric layer 106 and on the carrier substrate 100. In this case, the step of forming the barrier layer 122′ is carried out before or after the step of forming the embrittlement zone 112 in the piezoelectric layer 108. The assembling of the carrier substrate 100 with the substrate comprising a piezoelectric layer 106 then takes place at the interface between the two barrier layers 122′.

In another variant, the barrier layer 122 and dielectric layer 132′ of the intermediate structure 120′ can be provided on the piezoelectric layer 108 of the substrate comprising a layer 106 instead of on the carrier substrate 100. In this case, the step of forming the intermediate structure 120′ is carried out before or after the step of forming the embrittlement zone 112 in the piezoelectric layer 108. In this case, assembly of the carrier substrate 100 with the substrate comprising a piezoelectric layer 106 takes place at the interface between the barrier layer 122′ of the intermediate structure 120′ on the substrate comprising a piezoelectric layer 106 and the trapping layer 102 of the carrier substrate 100.

The piezoelectric-on-insulator (POI) substrate 144 shown in step V) of FIG. 2B comprises, in this order, the carrier substrate 100, the trapping layer 102, the dielectric layer 132′, the metal element diffusion barrier layer 122′ and the piezoelectric layer 114 according to this variant of the second embodiment of the disclosure.

In a second variant of the second embodiment shown in FIG. 2C, a step IIIb) for forming a dielectric layer 146 is added compared to the embodiment shown in FIG. 2B. In this step, the dielectric layer 146 is formed on the piezoelectric layer 108 of the substrate comprising a piezoelectric layer 106 after step IIa) of forming the embrittlement zone 112 in the piezoelectric layer 108.

The dielectric layer 146 is, for example, a silicon oxide-based layer. But the dielectric layer 146 can also be a layer of silicon nitride (Si₃N₄), or a layer comprising a combination of silicon nitride and oxide (SiOₓN_{y}), or a superposition of a layer of silicon oxide and a and a silicon nitride layer, or a combination of a silicon oxide layer, a silicon nitride layer and a silicon oxynitride layer (SiOₓN_{y}).

The dielectric layer 146 is produced by a deposition technique such as CVD or LPCVD (chemical vapor deposition), PECVD (plasma-enhanced chemical vapor deposition) or PVD (physical vapor deposition), or by oxidation heat treatment.

A surface treatment can be carried out to improve the surface quality of the deposited dielectric layer 146. Thus, in assembly step IV), the substrate comprising a piezoelectric layer 106 is assembled with the carrier substrate 100 to form the heterostructure 148 by bringing the barrier layer 122′ into contact with the dielectric layer 146. Thus, in this variant, assembly takes place at the interface 150 between the dielectric layer 146 of the substrate comprising a piezoelectric layer 106 and the barrier layer 122′ of the carrier substrate 100. The barrier layer 122′ is sandwiched between the two dielectric layers 132′ and 146.

In the same way as in the variants of the process according to the first embodiment, the dielectric layer 146 can be provided on the carrier substrate 100 on the barrier layer 122′ instead of on the substrate comprising a piezoelectric layer 106. In this case, the assembly between the carrier substrate 100 and the substrate comprising a piezoelectric layer 106 is made at the interface between the dielectric layer 146 of the carrier substrate 100 and the piezoelectric layer 108 of the substrate comprising a piezoelectric layer 106.

In the same way as in the other variants of the process according to the first embodiment, the dielectric layer can be provided on the piezoelectric substrate 106 and on the carrier substrate 100. The assembly of the carrier substrate 100 with the substrate comprising a piezoelectric layer 106 is then made at the interface between two dielectric layers of the same material, with oxide-oxide type bonds, in particular, a Si—O—Si type bond, which enables stable molecular force bonding.

As in the other variants, a dielectric layer of a first material can be provided on the substrate comprising a piezoelectric layer 106 and a dielectric layer of a second material can be provided on the carrier substrate 100, the first material being different from the second material. For example, the dielectric layer provided on the substrate comprising a piezoelectric layer 106 is a layer of Si₃N₄, while the dielectric layer provided on the carrier substrate 100 is a layer of SiOₓN_{y}, in particular, SiON. Thus, the assembly of the carrier substrate 100 with the substrate comprising a piezoelectric layer 106 is then carried out at the interface between two dielectric layers Si₃N₄—SiOₓN_{y}, which allows a stable bond.

As in the other variants of the second embodiment, one or more layers of the intermediate structure 120′ can be provided on the piezoelectric substrate 106 instead of on the carrier substrate 100.

The piezoelectric-on-insulator (POI) substrate 152 shown in step V) comprises the carrier substrate 100, the trapping layer 102, the dielectric layer 132′, a metal element diffusion barrier layer 122′, the second dielectric layer 146 and the piezoelectric layer 114 corresponds to the substrate according to the disclosure according to this second variant of the second embodiment.

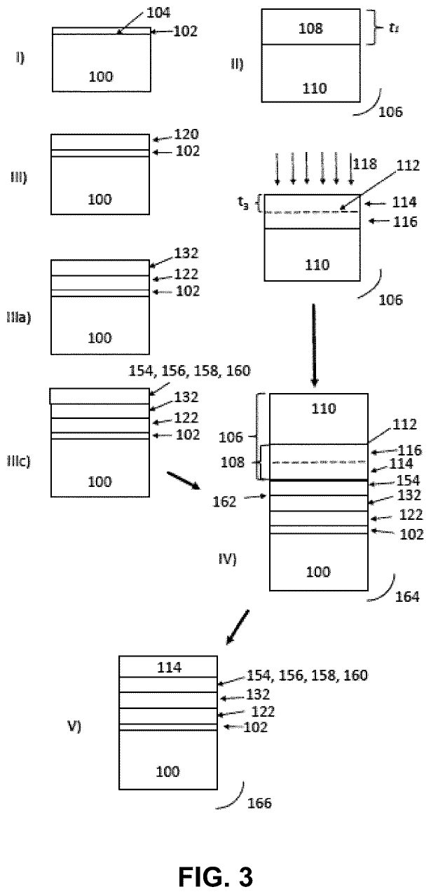

FIG. 3 schematically shows a process for manufacturing a piezoelectric-on-insulator (POI) substrate according to a third embodiment of the disclosure.

In this third embodiment, step III) of forming the intermediate structure 120 of the process according to FIG. 2A additionally comprises a step IIIc) of forming a second barrier layer 154 after step IIIa).

All the other steps I), II), IIa), III), IIIa), IV) and V) are the same as in the second embodiment according to FIG. 2A, except that in step IV) the assembly takes place between the second barrier layer 154 and the piezoelectric substrate 106. All features in common with the first or second embodiment and their variants and using the same reference numbers as above will not be described again, but reference is made to their detailed description above.

The intermediate structure 120 thus comprises a first metal element diffusion barrier layer 122, a dielectric layer 132 and a second barrier layer 154, 156, 158, 160.

This second barrier layer 154, 156, 158, 160 is deposited on the dielectric layer 132, which is deposited on the first barrier layer 122. The first barrier layer 122 and the second barrier layer 154 are separated by the dielectric layer 132.

In assembly step IV), the second barrier layer 154, 156, 158, 160 is brought into contact at the interface 162 with the substrate comprising a piezoelectric layer 106 to form the donor substrate 164.

The second barrier layer 154 can be a second metal element diffusion barrier layer 156. In this case, the second barrier layer 156 is formed in the same way as the first barrier layer 122. The second metal element diffusion barrier layer 156 can have the same properties, such as thickness or material as the first barrier layer 122, or alternatively the first metal element diffusion barrier layer 122 and the second barrier layer 156 can be different with different materials and/or thickness. For example, the first diffusion barrier layer 122 can be tantalum oxide (Ta₂O₅) or tantalum nitride (TaN) and the second diffusion barrier layer 156 can be silicon carbon nitride (SiCN) or aluminum oxide (Al₂O₃), or vice versa.

In a first embodiment, the second barrier layer 154 can be a hydrogen diffusion barrier layer 158 to limit hydrogen diffusion to the piezoelectric substrate 106 and/or to the trapping layer 102 of the carrier substrate 100. The hydrogen diffusion barrier layer 158 can be based on silicon oxynitride (SiOₓN_{y}) or aluminum nitride (AlN). This second barrier layer 158 based on silicon oxynitride (SiOₓN_{y}) or aluminum nitride (AlN) is formed by a PECVD (plasma-enhanced chemical vapor deposition) or PVD (physical vapor deposition) or ALD (atomic layer deposition) deposition technique, with thicknesses ranging from 5 nm to 100 nm.

Indeed, in a POI substrate, another source of degradation of the substrate's radio frequency and electrical performance is the diffusion of hydrogen to the piezoelectric layer and/or to the trapping layer during the POI substrate manufacturing process. Hydrogen can come from various sources, for example, from the bonding interface due to the hydrophilic nature of the bonding layers with the silicon-based substrate, or from the silicon oxide-based layer, which is rich in hydrogen due to its manufacturing process.

During a heat treatment, such as a deposition step or a fracturing step, carried out during the manufacturing process at temperatures of around 500° C., hydrogen, much like the metal element of the piezoelectric layer 114, can diffuse into the trapping layer 102 and neutralize the charge traps of the trapping layer 102. Moreover, hydrogen can also diffuse into the piezoelectric layer/substrate, wherein the presence of hydrogen can lower the Curie temperature, leading to local ferroelectric domain reversal. This phenomenon of local reversal of the ferroelectric domain affects the propagation of acoustic waves in the piezoelectric material.

In a second variant, the hydrogen diffusion barrier layer 158 is a silicon oxide-based layer 160. In this second variant, the second barrier layer 160 has a hydrogen concentration of less than 10²⁰ at/cm³, in particular, less than 10¹⁸ at/cm³. This can be achieved by depositing silicon oxide using plasma-enhanced chemical vapor deposition (PECVD), chemical vapor deposition (CVD or LPCVD), physical vapor deposition (PVD) or oxidation heat treatments. PVD deposition involves deposition temperatures between room temperature and 400° C., while the PECVD technique involves deposition temperatures between 150° C. and 400° C. LPCVD deposition involves deposition temperatures between 60° and 700° C. In this case, the dielectric layer 160 has a high hydrogen concentration of over 10²⁰ at/cm³.

To reduce the concentration of hydrogen in this second silicon oxide-based barrier layer 160, densification annealing is applied. This annealing is annealing in a hydrogen-depleted atmosphere (i.e., less than 5 ppm), and exposes the silicon oxide-based layer 160 to a temperature that is greater than its deposition temperature. This can be a neutral or oxidizing atmosphere. Preferentially, this temperature is greater than 800° C., typically between 800° C. and 900° C. The annealing stage is continued for at least one hour, and preferentially for several hours, in order to exodiffuse the hydrogen from the dielectric layer 160, and optionally from the trapping layer 102. After this densification annealing, the dielectric layer 160 has a hydrogen concentration of less than 10²⁰ at/cm³.

This type of densification annealing can, in particular, lead to the reduction of the diffusivity of the hydrogen, that is to say the ability of this species to diffuse into the material constituting the dielectric layer 160, so that the hydrogen, even with a concentration greater than 10²⁰ at/cm³ is less likely to diffuse toward the trapping layer 102. As a result, the trapping layer 102 also has a reduced hydrogen concentration, in particular, less than 10¹⁸ at/cm³.

In one embodiment, one or more layers of the intermediate structure 120, i.e., dielectric layer 132, barrier layer 122 and second barrier layer 154, 156, 158, 160, can be provided on the piezoelectric substrate 106 instead of on the carrier substrate 100. In this variant, the layers are deposited in such a way that the final POI substrate obtained after assembly and fracturing has the same layer sequence, i.e., the same order of deposited layers, as the POI 166 substrate obtained in the previously described embodiment.

In another variant of this embodiment of the disclosure, a dielectric layer can be provided on both substrates, the substrate comprising a piezoelectric layer 106 and on the carrier substrate 100. The assembly interface between the carrier substrate 100 and the substrate comprising a piezoelectric layer 106 is made at the interface between two dielectric layers, with oxide-oxide type bonds, in particular, a Si—O—Si type bond, which is a type of bond known to be stable.

In another variant of this embodiment of the disclosure, a dielectric layer of a first material can be provided on the substrate comprising a piezoelectric layer 106 and a dielectric layer of a second material can be provided on the carrier substrate 100, the first material being different from the second material. For example, the dielectric layer provided on the substrate comprising a piezoelectric layer 106 is a layer of Si₃N₄, while the dielectric layer provided on the carrier substrate 100 is a layer of SiOₓN_{y}, in particular, SiON. Thus, the assembly of the carrier substrate 100 with the substrate comprising a piezoelectric layer 106 is then carried out at the interface between two dielectric layers Si₃N₄—SiOₓN_{y}, which allows a stable bond.

The piezoelectric-on-insulator (POI) substrate 166 shown in step V) of FIG. 3 produced by the manufacturing process according to the disclosure comprises the carrier substrate 100, the trapping layer 102, the first metal element diffusion barrier layer 122, the dielectric layer 132, the second barrier layer 154, and the piezoelectric layer 114 and thus forms a POI substrate 166 according to the third embodiment.

The embodiments described are merely possible configurations, and it should be borne in mind that the individual features of the different embodiments can be combined with each other or provided independently of each other.

1. A piezoelectric-on-insulator (POI) substrate, comprising:
a carrier substrate comprising a trapping layer on a free surface of the carrier substrate;
a piezoelectric layer; and
an intermediate structure sandwiched between the piezoelectric layer and the trapping layer of the carrier substrate;
wherein the intermediate structure comprises at least one barrier layer for preventing diffusion of metal elements based on tantalum oxide (Ta₂O₅), the at least one barrier layer having a thickness t_{EM} greater than a predetermined thickness, the predetermined thickness being determined according to the thickness of the trapping layer in such a way that the metal element dose in the trapping layer is less than a predetermined threshold dose.

2. The piezoelectric-on-insulator (POI) substrate of claim 1, wherein the at least one barrier layer has a thickness t_{EM} of between 5 nm and 150 nm and a thickness tₚ of the trapping layer is between 50 nm and 5 μm.

3. The piezoelectric-on-insulator (POI) substrate of claim 1, wherein the intermediate structure comprises at least one dielectric layer in contact with the at least one barrier layer.

4. The piezoelectric-on-insulator (POI) substrate of claim 1, wherein the at least one barrier layer is sandwiched between two dielectric layers.

5. The piezoelectric-on-insulator (POI) substrate of claim 1, wherein the intermediate structure further comprises a second barrier layer.

6. The piezoelectric-on-insulator (POI) substrate of claim 5, wherein the second barrier layer is a hydrogen diffusion barrier layer.

7. The piezoelectric-on-insulator (POI) substrate of claim 1, wherein the intermediate structure comprises at least one layer with a hydrogen concentration of less than 10²⁰ at/cm³.

8. A method of manufacturing a piezoelectric-on-insulator (POI) substrate (130, 138, 144, 152, 160), the method comprising:
providing a carrier substrate comprising a trapping layer;
providing a substrate comprising a piezoelectric layer;
forming an intermediate structure on the substrate comprising a piezoelectric layer and/or on the carrier substrate, the formation of the intermediate structure comprising the formation of at least one barrier layer for preventing the diffusion of metal elements based on tantalum oxide (Ta₂O₅), the at least one barrier layer having a thickness t_{EM} greater than a predetermined thickness, the predetermined thickness being determined according to the thickness of the trapping layer in such a way that the metal element dose in the trapping layer is less than a predetermined threshold dose; and
assembling the substrate comprising a piezoelectric layer with the carrier substrate.

9. The method of claim 8, wherein the forming the intermediate structure further comprises forming a second barrier layer.

10. The method of claim 8, wherein the forming the intermediate structure further comprises forming a layer with a hydrogen concentration of less than 10²⁰ at/cm³.

11. The method of claim 9, wherein the forming the second barrier layer comprises forming a layer based on silicon nitride (SiN) or silicon oxynitride (SiOₓN_{y}) or aluminum nitride (AlN).

12. The method of claim 8, further comprising forming a dielectric layer on the carrier substrate and/or on the substrate comprising a piezoelectric layer prior to the step of assembly, such that an assembly interface is an oxide-oxide assembly interface.

13. The method of claim 8, further comprising forming a dielectric layer of a first material on the carrier substrate and/or of a second material different from the first material on the substrate comprising a piezoelectric layer prior to the assembling.

14. The method of claim 13, wherein the first material is based on silicon nitride and the second material is based on silicon oxynitride (SiOₓN_{y}).

15. The piezoelectric-on-insulator (POI) substrate of claim 1, wherein the trapping layer comprises a polycrystalline or amorphous or porous silicon-based layer.

16. The piezoelectric-on-insulator (POI) substrate of claim 1, wherein the piezoelectric layer comprises a lithium tantalate (LTO) or lithium niobate (LNO) layer.

17. The piezoelectric-on-insulator (POI) substrate of claim 1, wherein the at least one barrier layer is a lithium barrier layer.

18. The piezoelectric-on-insulator (POI) substrate of claim 17, wherein the predetermined thickness is determined according to the thickness of the trapping layer in such a way that the lithium dose in the trapping layer is less than a predetermined lithium threshold dose.

19. The piezoelectric-on-insulator (POI) substrate of claim 18, wherein the predetermined lithium threshold dose is less than 10¹² at/cm².

20. The piezoelectric-on-insulator (POI) substrate of claim 19, wherein the predetermined lithium threshold dose is less than 5×10¹¹ at/cm².
